(19) United States
(12) Patent Application Publication
(10) Pub. No.: US 2004/0046484 A1
(43) Pub. Date: Mar. 11, 2004

(54) Interface electronics for piezoelectric devices

(76) Inventor: Peter J. Schiller, Coon Rapids, MN (US)

Correspondence Address: Min S. (Amy) Xu, DORSEY & WHITNEY LLP, Suite 1500, 50 South Sixth Street, Minneapolis, MN, 55402-1498, US

(21) Appl. No.: 10/655,426

(22) Filed: Sep. 4, 2003

Related U.S. Application Data
(60) Provisional application No. 60/408,177, filed on Sep. 4, 2002.

(51) Int. Cl. H01L 41/09

(52) U.S. Cl. 310/317

(57) ABSTRACT

The present invention provides a method for improving the performance of piezoelectric devices and interface electronics for the piezoelectric devices, wherein an electrical field bias is applied to a piezoelectric material during a normal operation of the piezoelectric devices.

### CROSS-REFERENCE TO RELATED APPLICATION(S)

The present utility patent application claims priority of U.S. Provisional Patent Application, Serial No. 60/408,177 filed Sep. 4, 2002, subject matter of which is incorporated herewith by reference.

### FIELD OF THE INVENTION

The present invention relates generally to a piezoelectric device and method, and more particularly, to methods and interface electronic circuits to optimize performance and reliability of a piezoelectric device.

### BACKGROUND OF THE INVENTION

Piezoelectric materials are used in a variety of sensors and actuators. Piezoelectric materials convert mechanical energy to electrical energy and vice versa. For instance, if pressure is applied to a piezoelectric crystal, an electrical signal is generated in proportion thereby producing the function of a sensor. Generation of an electrical signal in response to an applied force or pressure is known as the “primary piezoelectric effect”. Similarly, if an electrical signal is applied to a piezoelectric crystal, it will expand in proportion as an actuator. Geometric deformation (expansion or contraction) in response to an applied electric signal is known as the “secondary piezoelectric effect”. Whether operated as a sensor or actuator, electrically conductive electrodes are appropriately placed on the piezoelectric crystal for collection or application of the electrical signal, respectively. Therefore, a piezoelectric sensor or actuator nominally includes a) a portion of piezoelectric material, and b) electrically-conductive electrodes suitably arranged to transfer electrical energy between the piezoelectric material and an electronic circuit.

Many piezoelectric materials undergo a process called “poling” to align the molecules and activate the piezoelectric properties. Poling generally involves the application of a large electric field, sometimes accompanied by high temperatures. After poling, a piezoelectric material can be used according to the primary or secondary piezoelectric effects to build sensors or actuators.

Piezoelectric materials have been utilized to create a variety of simple sensors and actuators. Examples of sensors include vibration sensors, microphones, and ultrasonic sensors. Examples of actuators include ultrasonic transmitters and linear positioning devices. However, in most of these examples, bulk piezoelectric material is machined and assembled in a coarse manner to achieve low-complexity devices.

The properties of piezoelectric materials can degrade over time through a variety of mechanisms. Piezoelectric materials have a tendency to “fatigue”. Fatigue occurs with repeated mechanical loading, during which the molecular alignment established at poling begins to degrade. Secondly, piezoelectric materials also “age”. Aging is a natural relaxation of the molecular alignment that occurs over time in the piezoelectric material, further degrading the piezoelectric properties. Lastly, “depoling” can occur in the piezoelectric material if an electric field is applied opposite to the original poling field. As the name implies, a depoling field tends to partially reverse the direction of molecular alignment, degrading the piezoelectric properties. It is very costly or impossible to perform the poling process a second time on bulk piezoelectric materials. Therefore, applications using sensors and actuators constructed from bulk piezoelectric materials require stringent limitations to prevent or reduce the extent of piezoelectric property degradation.

Unlike conventional bulk piezoelectric materials, thin film piezoelectrics can be integrated in a semiconductor process to create sensors with improved functionality and performance. Thin films of piezoelectric material are typically less than about 10 microns in thickness. Despite the advantages of thin film piezoelectrics, the effects of fatigue, aging, and depoling can also occur. In some cases, the degradation mechanisms may even be exaggerated with thin film piezoelectric materials.

Therefore, there is a need for specialized electronics and methods for interfacing with piezoelectric devices, particularly in thin film format.

### SUMMARY OF THE INVENTION

To solve the above and the other problems, the present invention provides a method of improving properties of a piezoelectric device by applying a suitable electrical field bias during operation. The present invention further provides a specific electronic circuitry that simultaneously applies an electrical field bias to a piezoelectric sensor while extracting electrical signals created by the piezoelectric sensor. The present invention further provides a specific electronic circuitry that simultaneously applies an electrical field bias to a piezoelectric actuator while applying actuation electrical signals to the actuator. Application of an electric field bias to the piezoelectric creates a static electric field within the piezoelectric material. The static electric field is oriented to reinforce a polarization direction within the piezoelectric material to reduce effects of fatigue, aging, and depoling while increasing electromechanical efficiency. The present invention thereby improves overall performance and reliability of piezoelectric devices.

Applying an electrical field bias to the piezoelectric device offers the following key advantages:

Response—Application of an electric field bias maximizes the molecular polarization within the piezoelectric, thereby maximizing the piezoelectric effect exhibited by the material and the electromechanical efficiency.

Reliability—With a suitably applied electrical field bias, properties of a piezoelectric device are more stable over long time periods. Effects of fatigue, aging, and depoling are reduced.

Accuracy—Application of a voltage bias maintains the polarization level within the piezoelectric, preventing the degradation that naturally occurs over time in piezoelectric materials. Response of the piezoelectric is thereby more stable over time and over a wider range of temperatures.

Cost—Conventional piezoelectric devices must be frequently recalibrated as their properties degrade over time. By reducing the degradation, recalibration is not required. The time and expense of sending parts out for calibration can be reduced or eliminated.

The above advantages are inherent to the present invention and enable novel configurations and unique features that increase the overall device and system performance.

These and other features and advantages of the present invention will become apparent to those skilled in the art from the following detailed description, wherein it is shown and described illustrative embodiments of the invention, including best modes contemplated for carrying out the invention. As it will be realized, the invention is capable of modifications in various obvious aspects, all without departing from the spirit and scope of the present invention. Accordingly, the drawings and detailed description are to be regarded as illustrative in nature and not restrictive.

### BRIEF DESCRIPTION OF THE DRAWINGS

FIG. 1 is a circuit schematic diagram of a conventional arrangement of a piezoelectric sensor.

FIG. 2 is a circuit schematic diagram of one embodiment of a single-ended piezoelectric sensor in accordance with the principles of the present invention.

FIG. 3 is a circuit schematic diagram of another embodiment of a single-ended piezoelectric sensor in accordance with the principles of the present invention.

FIG. 4 is a circuit schematic diagram of one embodiment of a differential piezoelectric sensor in accordance with the principles of the present invention.

FIG. 5 is a circuit schematic diagram of a preferred embodiment of a single-ended piezoelectric sensor in accordance with the principles of the present invention.

FIG. 6 is a circuit schematic diagram of another preferred embodiment of a singleended piezoelectric sensor in accordance with the principles of the present invention.

FIG. 7 is a circuit schematic diagram of yet another preferred embodiment of a singleended piezoelectric sensor in accordance with the principles of the present invention.

FIG. 8 is a circuit schematic diagram of still another preferred embodiment of a singleended piezoelectric sensor in accordance with the principles of the present invention.

FIG. 9 is a circuit schematic diagram of a preferred embodiment of a differential piezoelectric sensor in accordance with the principles of the present invention.

FIG. 10 is a circuit schematic diagram of a conventional arrangement of a piezoelectric actuator device.

FIG. 11 is a circuit schematic diagram of one embodiment of a piezoelectric actuator in accordance with the principles of the present invention.

FIG. 12 is a circuit schematic diagram of another embodiment of a piezoelectric actuator in accordance with the principles of the present invention.

### DETAILED DESCRIPTION OF THE PREFERRED EMBODIMENTS

The present invention provides a method for improving the performance of sensors and actuators that use piezoelectric materials, wherein an electric field bias is applied to the piezoelectric material. The present invention also provides a plurality of circuit embodiments for applying the electric field bias while simultaneously retaining the desired operation of a piezoelectric device.

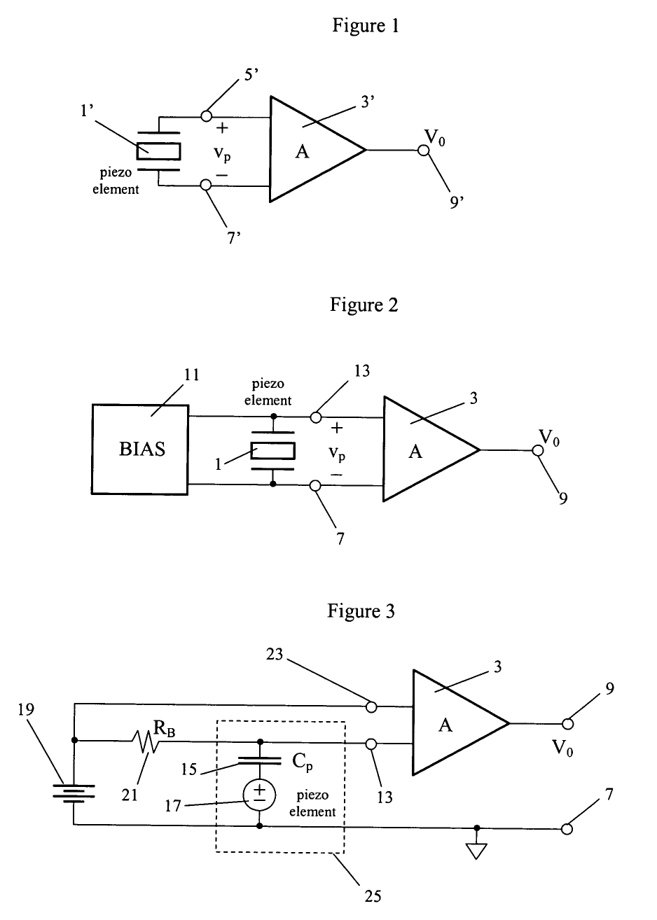

A conventional arrangement for piezoelectric sensors is shown in FIG. 1 and involves a direct connection between a piezoelectric sensor element 1′ and an electronic signal amplifier 3′. The piezoelectric sensor element 1′ generates a first piezoelectric signal in response to physical stimulus such as force, acceleration, or pressure. The first piezoelectric signal is connected between circuit terminals 5′ and 7′. The circuit terminals 5′ and 7′ are also connected to input terminals of the electronic signal amplifier 3′ that generates an electronic signal output 9′. The electronic signal amplifier 3′ may generate the electronic signal output 9′ in proportion to the voltage difference at the inputs connected to the circuit terminals 5′ and 7′. That is, the electronic signal output 9′ may be proportional to the first piezoelectric signal.

FIG. 2 illustrates one embodiment of a single-ended piezoelectric sensor in accordance with the principles of the present invention. In FIG. 2, a piezoelectric sensor element 1 is connected to an electronic signal amplifier 3 and further connected to an electric field bias generator 11. Similar to the arrangement of FIG. 1, the piezoelectric sensor element 1 generates a first piezoelectric signal in response to physical stimulus such as force, acceleration, or pressure and the electronic signal amplifier 3 generates an electronic signal output 9 in proportion. In accordance with the present invention, the electric field bias generator 11 applies an electric field bias signal to the piezoelectric sensor element 1 during normal operation to reduce the effects of fatigue, aging, and depoling while increasing the electromechanical efficiency.

Another embodiment of the single-ended piezoelectric sensor in accordance with the principles of the present invention is shown in FIG. 3. In FIG. 3, a piezoelectric sensor element 25 is distributed into equivalent circuit elements comprising an equivalent piezoelectric sensor capacitance 15 and a piezoelectric signal 17. The piezoelectric signal 17 is generated by the piezoelectric sensor element 25 in response to physical stimulus such as force, acceleration, or pressure. The electric field bias generator in FIG. 3 is accomplished by connecting the piezoelectric sensor element 25 to a voltage bias 19 through a bias resistor 21. The result is that over a long period of time the average voltage bias at a first circuit terminal 13 is equal to the voltage bias 19. Over shorter periods of time, the voltage bias at the first circuit terminal 13 is equal to the piezoelectric signal 17 generated by the piezoelectric sensor element 25.

Also shown in FIG. 3, the voltage bias 19 is also connected to a second circuit terminal 23. The inputs of electronic signal amplifier 3 are connected to the first circuit terminal 13 and the second circuit terminal 23. The electronic signal amplifier 3 generates the electrical signal output 9 in proportion to the voltage difference between the first circuit terminal 13 and the second circuit terminal 23.

In FIG. 3, the value of the bias resistor 21 is set depending on the application requirements. For example, if the application requires that physical stimulus with a frequency greater than 1000 Hz (1000 cycles per second) appear at the electrical signal output 9 and the piezoelectric sensor capacitance 15 is 330 pico-Farads, then the bias resistor 21 will be selected to be greater than about 480,000 ohms. If the required frequency response is lower, then the bias resistor 21 must be greater, and if the required frequency response is higher, then the bias resistor 21 can be smaller. In summary, the value of the bias resistor 21 in conjunction with the piezoelectric sensor capacitance 15 determines the frequency range over which the electrical signal output 9 is proportional to the electrical signal 17.

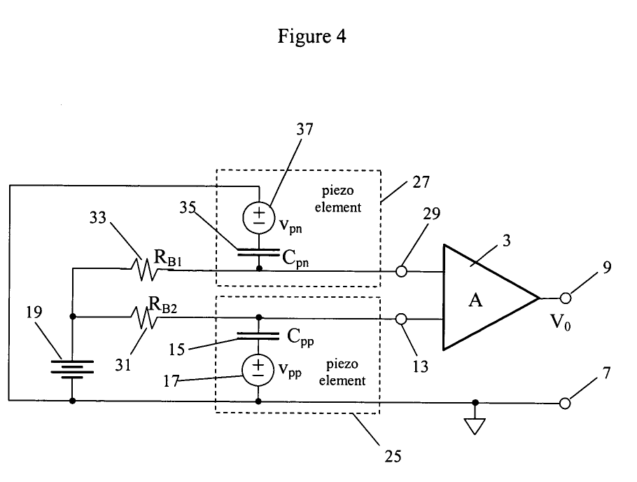

One embodiment of a differential piezoelectric sensor in accordance with the principles of the present invention is shown in FIG. 4. In FIG. 4, a first piezoelectric sensor element 25 is distributed into equivalent circuit elements comprising an equivalent piezoelectric sensor capacitance 15 and a first piezoelectric signal 17. A second piezoelectric sensor element 27 is distributed into equivalent circuit elements comprising an equivalent piezoelectric sensor capacitance 35 and a second piezoelectric signal 37. The first piezoelectric signal 17 is generated by the first piezoelectric sensor element 25 in response to physical stimulus such as force, acceleration, or pressure. Similarly, the second piezoelectric signal 37 is generated by the second piezoelectric element 27 in response to physical stimulus such as force, acceleration, or pressure. The electric field bias generator in FIG. 4 is accomplished by connecting the first and second piezoelectric sensor elements 25 and 27 to a voltage bias 19 through bias resistors 31 and 33. The result is that over a long period of time the average voltage bias at a first circuit terminal 13 and a second circuit terminal 29 is equal to the voltage bias 19. Over shorter periods of time, the voltage bias at the first circuit terminal 13 is equal to the first piezoelectric signal 17 generated by the first piezoelectric sensor element 25. Similarly, over shorter periods of time, the voltage bias at the second circuit terminal 29 is equal to the second piezoelectric signal 37 generated by the second piezoelectric sensor element 27. The inputs of electronic signal amplifier 3 are connected to the first circuit terminal 13 and the second circuit terminal 29. The electronic signal amplifier 3 generates an electrical signal output 9 in proportion to the voltage difference between first circuit terminal 13 and second circuit terminal 29.

In FIG. 4, the values of the bias resistors 31 and 33 are set depending on the application requirements. For example, if the application requires that physical stimulus with a frequency greater than 1000 Hz (1000 cycles per second) appear at the electrical signal output 9 and the piezoelectric sensor capacitances 15 and 35 are each 330 pico-Farads, then the bias resistors 31 and 33 will each be selected to be greater than about 480,000 ohms. If the required frequency response is lower, then the bias resistors 31 and 33 must be greater than about 480,000 ohms; and if the required frequency response is higher, then the bias resistors 31 and 33 can be smaller than about 480,000 ohms. In summary, the values of the bias resistors 31 and 33 in conjunction with the piezoelectric sensor capacitances 15 and 35 determine the frequency range over which the electrical signal output 9 is proportional to the difference between the first piezoelectric signal 17 and the second piezoelectric signal 37.

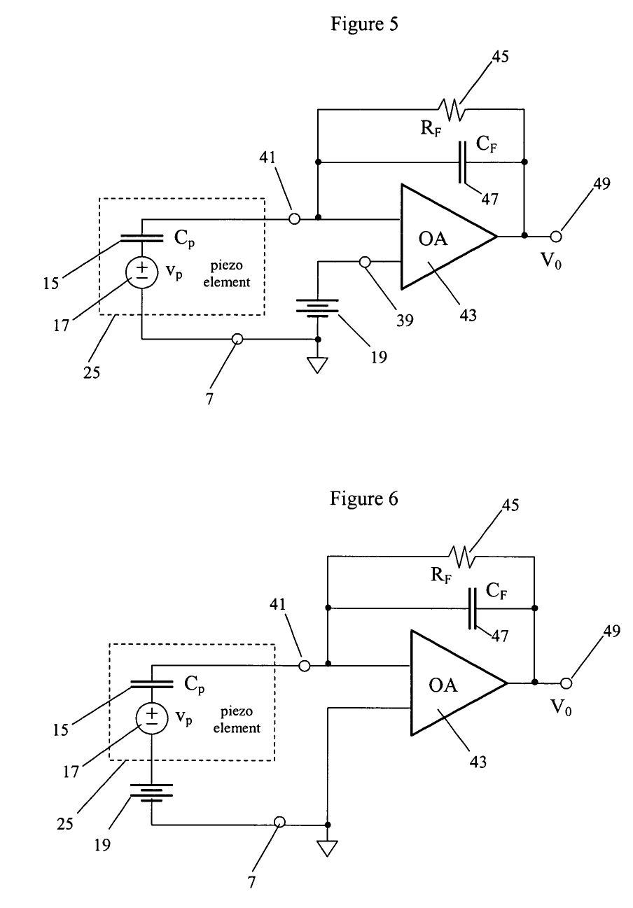

A preferred embodiment of the present invention for a single-ended piezoelectric sensor is shown in FIG. 5. In FIG. 5, the piezoelectric sensor element 25 is distributed into equivalent circuit elements comprising the piezoelectric sensor capacitance 15 and the piezoelectric signal 17. The piezoelectric signal 17 is generated by the piezoelectric sensor element 25 in response to physical stimulus such as force, acceleration, or pressure. The electric field bias generator in FIG. 5 is accomplished by connecting the piezoelectric sensor element 25 to the input of an operational amplifier 43 and a feedback network comprising a feedback capacitor 47 and a feedback resistor 45. The voltage bias 19 is connected to a second input of the operational amplifier 43. During a normal operation, the two inputs of the operational amplifier 43 at circuit terminals 39 and 41 are at approximately the same voltage level. It is appreciated that details of the operational amplifier 43 are understood by a person skilled in the field. The operational amplifier 43 in conjunction with the feedback capacitor 47 and the feedback resistor 45 create a charge amplifier that generates an electrical signal output 49 in proportion to the piezoelectric signal 17. The constant of proportionality between the electrical signal output 49 and the piezoelectric signal 17 is approximately equal to the ratio of the values of the equivalent piezoelectric sensor capacitance 15 and the feedback capacitor 47. The frequency response of the charge amplifier is determined by the pole of the feedback capacitor 47 and the feedback resistor 45. Over a long period of time the average electrical signal output 49 is equal to the voltage bias 19. Over shorter periods of time, the electrical signal output 49 is proportional to the piezoelectric signal 17 generated by the piezoelectric sensor element 25.

Another preferred embodiment of the present invention for a single-ended piezoelectric sensor is shown in FIG. 6. In FIG. 6, the piezoelectric sensor element 25 is distributed into equivalent circuit elements comprising the piezoelectric sensor capacitance 15 and the first piezoelectric signal 17. The piezoelectric signal 17 is generated by the piezoelectric sensor element 25 in response to physical stimulus such as force, acceleration, or pressure. The electric field bias generator in FIG. 6 is accomplished by connecting the piezoelectric sensor element 25 at a circuit terminal 41 to the input of the operational amplifier 43 and the feedback network comprising the feedback capacitor 47 and the feedback resistor 45. The piezoelectric sensor element 25 is further connected to a voltage bias 19 while a second input of the operational amplifier 43 is connected to a reference voltage at the circuit terminal 7. During a normal operation, the two inputs of the operational amplifier 43 at circuit terminals 7 and 41 are at approximately the same voltage level. It is appreciated that details of the operational amplifier 43 are understood by a person skilled in the field. The operational amplifier 43 in conjunction with the feedback capacitor 47 and the feedback resistor 45 create a charge amplifier that generates the electrical signal output 49 in proportion to the piezoelectric signal 17. The constant of proportionality between the electrical signal output 49 and piezoelectric signal 17 is approximately equal to the ratio of the values of the equivalent piezoelectric sensor capacitance 15 and the feedback capacitor 47. The frequency response of the charge amplifier is determined by the pole of the feedback capacitor 47 and the feedback resistor 45. Over a long period of time the average electrical output signal 49 is equal to the reference voltage at the circuit terminal 7. Over shorter periods of time, the electrical signal output 49 is proportional to the piezoelectric signal 17 generated by the piezoelectric sensor element 25.

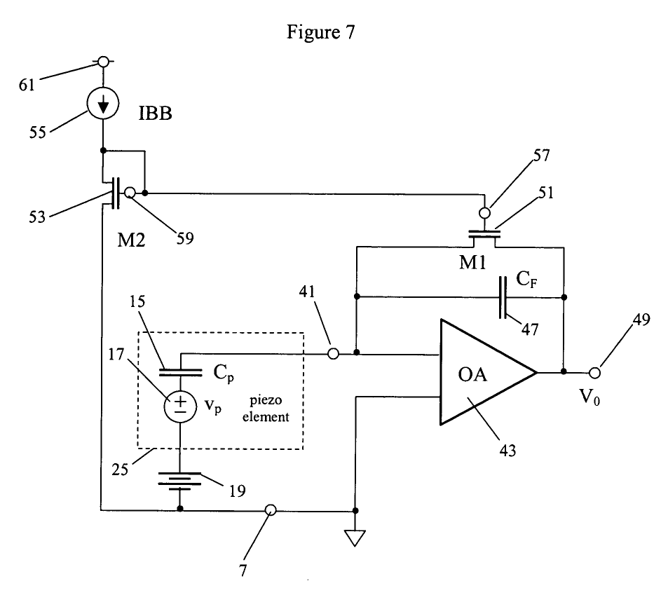

There are many ways to implement signal amplifiers in consistent with the circuit arrangement shown in FIG. 6. Still another preferred embodiment of the present invention for a single-ended piezoelectric sensor is shown in FIG. 7. In FIG. 7, the feedback resistor 45 in FIG. 6 is replaced with a field effect transistor 51. In FIG. 7, the piezoelectric sensor element 25 is distributed into equivalent circuit elements comprising the piezoelectric sensor capacitance 15 and the piezoelectric signal 17. The piezoelectric signal 17 is generated by the piezoelectric sensor element 25 in response to physical stimulus such as force, acceleration, or pressure. The electric field bias generator in FIG. 7 is accomplished by connecting the piezoelectric sensor element 25 at a circuit terminal 41 to the input of the operational amplifier 43 and the feedback network comprising the feedback capacitor 47 and the feedback transistor 51. The piezoelectric sensor element 25 is further connected to the voltage bias 19 while the second input of the operational amplifier 43 is connected to a reference voltage at circuit terminal 7. During a normal operation, the two inputs of the operational amplifier 43 at the circuit terminals 7 and 41 are at approximately the same voltage level. It is appreciated that details of the operational amplifier 43 are understood by a person skilled in the field. The operational amplifier 43 in conjunction with the feedback capacitor 47 and the feedback transistor 51 create a charge amplifier that generates the electrical signal output 49 in proportion to the piezoelectric signal 17. The constant of proportionality between the electrical signal output 49 and the piezoelectric signal 17 is approximately equal to the ratio of the values of the equivalent piezoelectric sensor capacitance 15 and the feedback capacitor 47. The frequency response of the charge amplifier is determined by the pole of the feedback capacitor 47 and the feedback transistor 51. Over a long period of time the average electrical signal output 49 is equal to the reference voltage at the circuit terminal 7. Over shorter periods of time, the electrical signal output 49 is proportional to the piezoelectric signal 17 generated by the piezoelectric sensor element 25.

In FIG. 7, the feedback transistor 51 is selected and operated with an equivalent resistance value that achieves the desired frequency response. The voltage at a control terminal 57 on the feedback transistor 51 sets the equivalent resistance. One method for generating the voltage at the control terminal 57 is to force an electrical current 55 to flow through a bias transistor 53 from a voltage supply 61. The bias transistor 53 is configured with its control terminal 59 connected to the control terminal 57 of the feedback transistor 51.

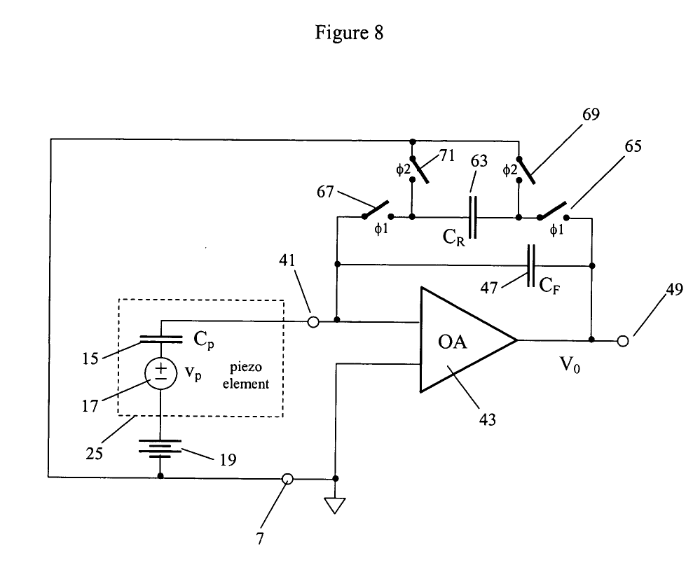

Still another preferred embodiment of the present invention for a single-ended piezoelectric sensor is shown in FIG. 8. In FIG. 8, the feedback resistor 45 of FIG. 6 is replaced with a switched capacitor network comprising a switched capacitor 63 and switches 65, 67, 69, and 71. In FIG. 8, the piezoelectric sensor element 25 is distributed into equivalent circuit elements comprising the piezoelectric sensor capacitance 15 and the piezoelectric signal 17. The piezoelectric signal 17 is generated by the piezoelectric sensor element 25 in response to physical stimulus such as force, acceleration, or pressure. The electric field bias generator in FIG. 8 is accomplished by connecting the piezoelectric sensor element 25 at the circuit terminal 41 to the input of the operational amplifier 43 and the feedback network comprising the feedback capacitor 47 and the switched capacitor network 63, 65, 67, 69, and 71. The piezoelectric sensor element 25 is further connected to the voltage bias 19 while the second input of the operational amplifier 43 is connected to the reference voltage at the circuit terminal 7. During a normal operation, the two inputs of the operational amplifier 43 at the circuit terminals 7 and 41 are at approximately the same voltage level. It is appreciated that details of the operational amplifier 43 are understood by a person skilled in the field. The operational amplifier 43 in conjunction with the feedback capacitor 47 and the switched capacitor network 63, 65, 67, 69, and 71 create a charge amplifier that generates the electrical signal output 49 in proportion to the piezoelectric signal 17. The constant of proportionality between the electrical signal output 49 and the piezoelectric signal 17 is approximately equal to the ratio of the values of the equivalent piezoelectric sensor capacitance 15 and the feedback capacitor 47. The frequency response of the charge amplifier is determined by the pole of the feedback capacitor 47 and the switched capacitor network 63, 65, 67, 69, and 71. Over a long period of time the average electrical signal output 49 is equal to the reference voltage at the circuit terminal 7. Over shorter periods of time, the electrical signal output 49 is proportional to the piezoelectric signal 17 generated by the piezoelectric sensor element 25.

In FIG. 8, the switched capacitor network 63, 65, 67, 69, and 71 is selected and operated with an equivalent resistance value that achieves the desired frequency response. The equivalent resistance of the switched capacitor network is determined by the value of the switched capacitor 63 and the frequency at which the switches are operated. It is appreciated that the details of switched capacitor networks are understood by a person skilled in the field and there are several known ways to achieve an equivalent resistor. In FIG. 8, the switches 65 and 67 operate in unison while the switches 69 and 71 operate in unison. When the switches 65 and 67 are open, the switches 69 and 71 are closed. When the switches 65 and 67 are closed, the switches 69 and 71 are open. Opening and closing of the switches 65, 67, 69, and 71 cycles continuously at a clock frequency. The equivalent resistance of the switched capacitor network 63, 65, 67, 69, and 71 is determined by the clock frequency and the value of the switched capacitor 63. Higher equivalent resistance is achieved with lower values for the switched capacitor 63 or lower clock frequency. Lower equivalent resistance is achieved with higher values for the switched capacitor 63 or higher clock frequency.

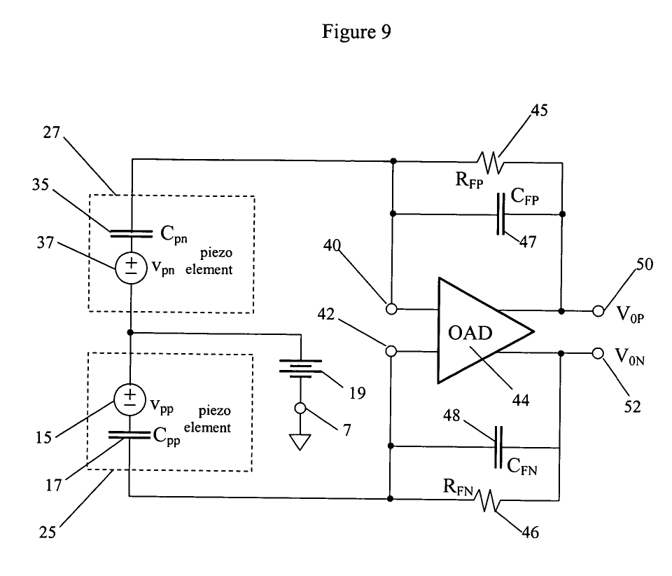

A preferred embodiment of the present invention for a differential piezoelectric sensor is shown in FIG. 9. In FIG. 9, a first piezoelectric sensor element 25 is distributed into equivalent circuit elements comprising an equivalent piezoelectric sensor capacitance 15 and the first piezoelectric signal 17. A second piezoelectric sensor element 27 is distributed into equivalent circuit elements comprising an equivalent piezoelectric sensor capacitance 35 and a second piezoelectric signal 37. The first piezoelectric signal 17 is generated by the first piezoelectric sensor element 25 in response to physical stimulus such as force, acceleration, or pressure. The second piezoelectric signal 37 is generated by the second piezoelectric element 27 in response to physical stimulus such as force, acceleration, or pressure. The electric field bias generator in FIG. 9 is accomplished by connecting the piezoelectric sensor elements 25 and 27 at circuit terminals 40 and 42 to the inputs of a differential operational amplifier 44. The differential operational amplifier 44 has an inverting input at the circuit terminal 40, a noninverting input at the circuit terminal 42, a non-inverting output at a circuit terminal 50, and an inverting output at a circuit terminal 52. A first feedback network comprising a first feedback capacitor 47 and a first feedback resistor 45 is connected between the circuit terminals 50 and 40. A second feedback network comprising a second feedback capacitor 48 and a second feedback resistor 46 is connected between the circuit terminals 52 and 42. It is appreciated that the differential operational amplifier 44 is understood by a person skilled in the field. The piezoelectric sensor elements 25 and 27 are further connected to a voltage bias 19. During a normal operation, the two inputs of the differential operational amplifier 44 at the circuit terminals 40 and 42 are at approximately the same voltage level as the reference voltage level at the terminal 7. The operational amplifier 44 in conjunction with the feedback capacitors 47 and 48 and the feedback resistors 45 and 46 create a differential charge amplifier that generates a differential signal output between the circuit terminals 50 and 52 in proportion to the difference between the first piezoelectric signal 17 and the second piezoelectric signal 37. The constant of proportionality between the differential signal output at the terminals 50 and 52 and the difference between the first piezoelectric signal 17 and the second piezoelectric signal 37 is approximately equal to the ratio of the values of the equivalent piezoelectric sensor capacitances 15 and 35 and the feedback capacitors 47 and 48. The frequency response of the charge amplifier is determined by the pole of the feedback capacitors 47 and 48 and the feedback resistors 45 and 46. Over a long period of time the average electrical output signals at the terminals 50 and 52 are equal to the reference voltage at circuit terminal 7. Over shorter periods of time, the differential electrical signal output between terminals 50 and 52 is proportional to the difference between the first piezoelectric signal 17 generated by the first piezoelectric sensor element 25 and the second piezoelectric signal 37 generated by the second piezoelectric sensor element 27.

It is appreciated that the feedback resistors 45 and 46 in FIG. 9 may be replaced with the other circuit components, such as a field effect transistor or a switched capacitor network, to achieve a similar effect.

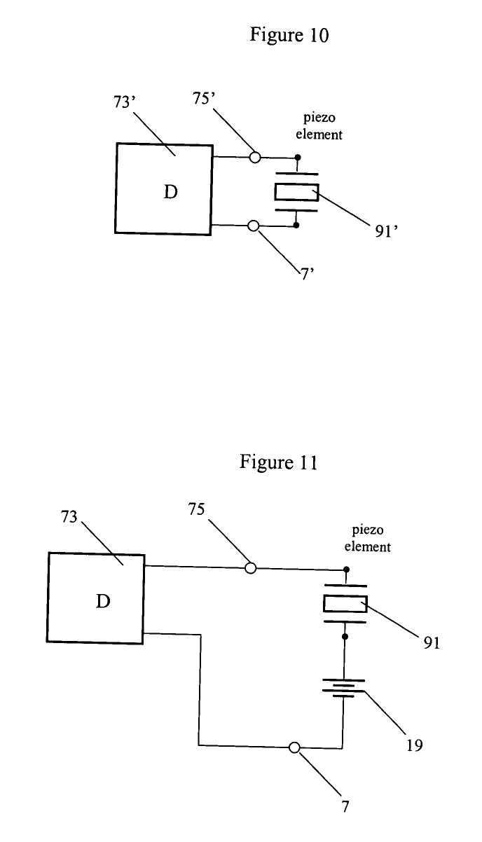

A conventional arrangement for piezoelectric actuators is shown in FIG. 10 and involves a direct connection between a piezoelectric actuator element 91 ′ and an electronic drive signal generator 73′. The piezoelectric actuator element 91 ′ generates a physical motion in response to the electronic drive signal at a terminal 75′.

FIG. 11 illustrates one embodiment of a piezoelectric actuator in accordance with the principles of the present invention. The piezoelectric actuator includes a piezoelectric actuator element 91 connected to an electronic drive signal generator 73 and further connected to a voltage bias 19. The piezoelectric actuator element 91 generates a physical motion in response to the electronic drive signal at a terminal 75 generated by the drive signal generator 73. The presence of the bias voltage 19 maintains an electric field bias in the piezoelectric material of the piezoelectric actuator element 91 to reduce the effects of fatigue, aging, and depoling while increasing electromechanical efficiency.

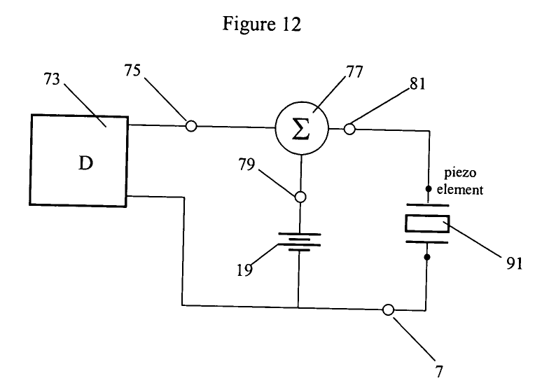

An alternative embodiment of the piezoelectric actuator in accordance with the principles of the present invention is shown in FIG. 12. In FIG. 12, the piezoelectric actuator element 91 is connected to a signal summing circuit 77 at a terminal 81 and a reference terminal 7. The electronic drive signal generator 73 generates a drive signal at the terminal 75 that is also connected to a first input of the signal summing circuit 77. The voltage bias 19 is connected at a terminal 79 to a second input of the signal summing circuit 77. The signal summing circuit 77 generates an electrical signal output at a terminal 81 that is the sum of the signal inputs at the terminals 75 and 79. The piezoelectric actuator element 91 generates a physical motion in response to the electronic drive signal at the terminal 75 generated by the drive signal generator 73. The presence of the bias voltage 19 maintains an electric field bias in the piezoelectric material of the piezoelectric actuator element 91 to reduce the effects of fatigue, aging, and depoling while increasing electromechanical efficiency.

From the above description and drawings, it will be understood by those of ordinary skill in the art that the particular embodiments shown and described are for purposes of illustration only and are not intended to limit the scope of the present invention. Those of ordinary skill in the art will recognize that the present invention may be embodied in other specific forms without departing from its spirit or essential characteristics. References to details of particular embodiments are not intended to limit the scope of the invention.

What is claimed is:

1. A method of operating a piezoelectric device capable of reducing an effect of a piezoelectric material, comprising the steps of:
connecting an electrical field bias to the piezoelectric device; and
applying the electrical field bias to the piezoelectric device during an operation of the piezoelectric device.

2. The method of claim 1 wherein the piezoelectric device is a piezoelectric sensor element, and the step of applying the electrical field bias comprises connecting a voltage bias to the piezoelectric sensor element through a circuit impedance component.

3. The method of claim 1 wherein the piezoelectric device is a piezoelectric actuator element, and the step of applying the electrical field bias comprises adding a voltage bias to an electrical actuation signal.

4. An electrical circuit for amplifying a voltage output of a piezoelectric sensor, comprising:
a voltage amplifier for generating an electrical signal output proportional to the voltage output of the piezoelectric sensor; and
a bias network that applies an electrical field bias to the piezoelectric sensor.

5. The electrical circuit of claim 4 wherein the bias network is comprised of a circuit impedance component connected to a voltage bias.

6. An electrical circuit for amplifying the voltage outputs of a plurality of piezoelectric sensors, comprising:
a voltage amplifier for generating an electrical signal output proportional to difference of the voltage outputs of the plurality of piezoelectric sensors; and
a bias network that applies an electrical field bias to the plurality of piezoelectric sensors.

7. The electrical circuit of claim 6 wherein the bias network is comprised of circuit impedance components connected to a voltage bias.

8. An electrical circuit for amplifying a charge output of a piezoelectric sensor, comprising:
a charge amplifier for generating an electrical signal output proportional to the charge output of the piezoelectric sensor; and
a bias network that applies an electrical field bias to the piezoelectric sensor.

9. The electrical circuit of claim 8 wherein the bias network is comprised of a circuit impedance component connected to a voltage bias.

10. An electrical circuit for amplifying charge outputs of a plurality of piezoelectric sensors, comprising:
a charge amplifier for generating an electrical signal output proportional to difference of the charge outputs of the plurality of piezoelectric sensors; and
a bias network that applies an electrical field bias to the plurality of piezoelectric sensors.

11. The electrical circuit of claim 10 wherein the bias network is comprised of circuit impedance components connected to a voltage bias.

12. An electrical circuit for driving a piezoelectric actuator, comprising:
a primary driver circuit for generating an actuation signal output and a secondary driver circuit for generating an electrical field bias.

13. A piezoelectric sensor device capable of reducing an effect of a piezoelectric material, comprising an electrical circuit for sensing and amplifying an output of the piezoelectric sensor device.

14. The piezoelectric sensor device of claim 13, wherein the piezoelectric material is a thin-film piezoelectric material.

15. A piezoelectric actuator device capable of reducing an effect of a piezoelectric material, comprising an electrical circuit for driving the actuator device to generate an actuation signal output and an electrical field bias.

16. The piezoelectric actuator device of claim 15, wherein the piezoelectric material is a thin-film piezoelectric material.
